(19) United States
(12) Patent Application Publication
(10) Pub. No.: US 2014/0332883 A1
(43) Pub. Date: Nov. 13, 2014

(54) Semiconductor Device Having Dummy Gate and Gate

(71) Applicant: Samsung Electronics Co., Ltd., Suwon-si (KR)

(72) Inventors: Eun-Kyoung Kwon, Suwon-si (KR); Hee-Soo Kang, Seoul (KR); Han-Gu Kim, Seongnam-si (KR); Woo-Jin Seo, Hwaseong-si (KR); Ki-Tae Lee, Seongnam-si (KR); Jae-Gon Lee, Hwaseong-si (KR); Chan-Hee Jeon, Hwaseong-si (KR)

(73) Assignee: Samsung Electronics Co., Ltd., Suwon-si (KR)

(21) Appl. No.: 14/089,274

(22) Filed: Nov. 25, 2013

(30) Foreign Application Priority Data
May 7, 2013 (KR) 10-2013-0051353

(51) Int. Cl. H01L 27/088

(52) U.S. Cl. CPC H01L 27/0886
USPC 257/336

(57) ABSTRACT

A fin-shaped active region is defined on a substrate. First and second gate electrodes crossing the fin-shaped active region are arranged. A dummy gate electrode is formed between the first and second gate electrodes. A first drain region is formed between the first gate electrode and the dummy gate electrode. A second drain region is formed between the dummy gate electrode and the second gate electrode. A source region facing the second drain region is formed. A first drain plug relatively close to the dummy gate electrode, relatively far from the second gate electrode, and connected to the second drain region is formed. The second gate electrode is arranged between the second drain region and the source region. Each of the first and second gate electrodes covers a side surface of the fin-shaped active region.

### CROSS-REFERENCE TO RELATED APPLICATION

This application claims priority under 35 U.S.C. §119 to Korean Patent Application No. 10-2013-0051353 filed on May 7, 2013, the disclosure of which is hereby incorporated by reference in its entirety.

### BACKGROUND

1. Field

Embodiments of the inventive concept relate to a semiconductor device having a dummy gate formed between gates.

2. Description of Related Art

Various methods are being studied in order to improve performance of an electrostatic discharge (ESD) protection device which prevents damage to internal circuits formed on a semiconductor device.

### SUMMARY

Embodiments of the inventive concept provide a semiconductor device having an ESD protection device that prevents damage to internal circuits.

In accordance with some embodiments of the inventive concept, an ESD protection device includes a fin-shaped active region defined on a substrate, first and second gate electrodes crossing the fin-shaped active region and spaced apart from each other, a dummy gate electrode formed between the first and second gate electrodes, crossing the fin-shaped active region, and covering a side surface of the fin-shaped active region, a first drain region formed in the active region disposed between the first gate electrode and the dummy gate electrode, a second drain region formed in the active region disposed between the dummy gate electrode and the second gate electrode, a source region formed in the fin-shaped active region and spaced apart from the second drain region, and a first drain plug connected to the second drain region. The second gate electrode is arranged between the second drain region and the source region. Each of the first and second gate electrodes covers the side surface of the fin-shaped active region. The distance between the first drain plug and the second gate electrode is greater than that between the first drain plug and the dummy gate electrode.

In some embodiments, a metal silicide layer may be formed between the first drain plug and the second drain region. The metal silicide layer may be relatively close to the dummy gate electrode, and relatively far from the second gate electrode. The distance between the metal silicide layer and the second gate electrode may be greater than that between the metal silicide layer and the dummy gate electrode.

In other embodiments, a spacer may be formed on a side surface of the dummy gate electrode. The metal silicide layer may be in contact with the spacer.

In still other embodiments, the first drain plug may be in contact with the spacer.

In still other embodiments, a second drain plug relatively close to the dummy gate electrode and relatively far from the first gate electrode, and connected to the first drain region, may be formed. The distance between the second drain plug and the first gate electrode may be greater than that between the second drain plug and the dummy gate electrode.

In still other embodiments, the first and second drain plugs may cover the dummy gate electrode, and are connected to each other.

In still other embodiments, the first and second drain plugs may be in contact with the dummy gate electrode.

In still other embodiments, a lightly doped drain (LDD) in contact with the drain region and aligned with a side surface of the second gate electrode may be formed. A first side surface of the second drain region adjacent to the second gate electrode may be in contact with the LDD. A second side surface of the second drain region adjacent to the dummy gate electrode may be in direct contact with the fin-shaped active region.

In still other embodiments, a well may be formed in the fin-shaped active region under the dummy gate electrode. The fin-shaped active region may include first conductivity-type impurities. The well, the first drain region, and the second drain region may contain second conductivity-type impurities different from the first conductivity-type impurities. The well may be arranged between the first drain region and the second drain region. A lower end of the well may be formed at a lower level than the first drain region and the second drain region.

In still other embodiments, a third gate electrode crossing the fin-shaped active region and spaced apart from the second gate electrode may be formed. A source plug connected to the source region may be formed between the second gate electrode and the third gate electrode.

In still other embodiments, the distance between the second gate electrode and the third gate electrode may be smaller than that between the second gate electrode and the dummy gate electrode.

In still other embodiments, the first drain plug may be connected to an input/output pad. The first gate electrode, the second gate electrode, and the source region may be connected to a ground Vss or a power source Vdd.

In accordance with another aspect of the inventive concept, an ESD protection device includes an active region defined on a substrate, first to third gate electrodes crossing the active region and spaced apart from each other, a first dummy gate electrode formed between the first and second gate electrodes and crossing the active region, a second dummy gate electrode formed between the second and third gate electrodes and crossing the active region, a first drain region formed in the active region disposed between the first gate electrode and the first dummy gate electrode, a second drain region formed in the active region disposed between the first dummy gate electrode and the second gate electrode, a first source region formed in the active region between the second gate electrode and the second dummy gate electrode, a second source region formed in the active region between the second dummy gate electrode and the third gate electrode, a first drain plug adjacent to the first dummy gate electrode and connected to the second drain region, and a first source plug adjacent to the second dummy gate electrode and connected to the first source region.

In some embodiments, a second drain plug relatively close to the first dummy gate electrode and relatively far from the first gate electrode, and connected to the first drain region, may be formed. The distance between the second drain plug and the first gate electrode may be greater than that between the second drain plug and the first dummy gate electrode. A second source plug relatively close to the second dummy gate electrode and relatively far from the third gate electrode, and connected to the second source region, may be formed. The distance between the second source plug and the third gate electrode may be greater than that between the second source plug and the second dummy gate electrode.

In other embodiments, the first and second drain plugs may cover the first dummy gate electrode, and be connected to each other and in contact with the first dummy gate electrode. The first and second source plugs may cover the second dummy gate electrode, and be connected to each other and in contact with the second dummy gate electrode.

In some embodiments, an ESD protection device may include a fin-shaped active region defined on a substrate, a gate electrode crossing the fin-shaped active region, a dummy gate electrode spaced apart from the gate electrode, crossing the fin-shaped active region. The ESD protection device may also include a first drain region in the fin-shaped active region between the gate electrode and the dummy gate electrode and a source region in the fin-shaped active region. The gate electrode may be between the source region and the first drain region. The ESD protection device may further include a first drain plug connected to the first drain region. A distance between the first drain plug and the gate electrode may be greater than a distance between the first drain plug and the dummy gate electrode.

In some embodiments, the ESD protection device may also include a second drain region formed in the fin-shaped active region. The dummy gate electrode may be between the first drain region and the second drain region. The ESD protection device may further include a second drain plug connected to the second drain region. The distance between the second drain plug and the dummy gate electrode may be substantially equal to the distance between the first drain plug and the dummy gate electrode. The ESD protection device may also include a source plug connected to the source region. The distance between the source plug and the gate electrode may be greater than the distance between the first drain plug and the dummy gate electrode.

In some embodiments, the ESD protection device may include a first gate dielectric layer surrounding bottom and side surfaces of the gate electrode and dummy gate electrode, a second gate dielectric layer between the fin-shaped active region and the first gate dielectric layer, a first interlayer insulating layer and a second interlayer insulating layer on the first interlayer insulating layer. The upper ends of the first interlayer insulating layer, the gate electrode and the dummy gate electrode may be substantially on the same plane. In further embodiments, the first drain region may be connected to a first active circuit, the gate electrode may be connected to a second active circuit and the source region may be connected to ground.

Details of other embodiments are included in the detailed description and drawings.

### BRIEF DESCRIPTION OF THE DRAWINGS

The foregoing and other features and advantages of the inventive concepts will be apparent from the more particular description of preferred embodiments of the inventive concepts, as illustrated in the accompanying drawings in which like reference characters refer to the same parts throughout the different views. The drawings are not necessarily to scale, emphasis instead being placed upon illustrating the principles of the inventive concepts. In the drawings:

FIG. 1 is a perspective view for describing semiconductor devices in accordance with embodiments of the inventive concept, and FIG. 2 is an explosive perspective view of FIG. 1;

FIG. 3 is a schematic block diagram showing a part of a semiconductor device in accordance with embodiments of the inventive concept;

FIGS. 4A and 4B are equivalent circuit diagrams showing parts of semiconductor devices in accordance with embodiments of the inventive concept;

FIG. 5A is a layout showing a part of a semiconductor device in accordance with embodiments of the inventive concept, and FIG. 5B is an enlarged view showing a part of FIG. 5A in detail;

FIG. 6 is a part of a cross-sectional view taken along line I-I′ of FIG. 5A for describing a semiconductor device in accordance with embodiments of the inventive concept;

FIG. 7 is a cross-sectional view taken along line II-II′ of FIG. 5B for describing a semiconductor device in accordance with embodiments of the inventive concept;

FIG. 8 is a cross-sectional view taken along line of III-III′ FIG. 5B for describing a semiconductor device in accordance with embodiments of the inventive concept;

FIG. 9 is a cross-sectional view taken along line IV-IV′ of FIG. 5B for describing a semiconductor device in accordance with embodiments of the inventive concept;

FIGS. 10 to 16 are cross-sectional views for describing semiconductor devices in accordance with embodiments of the inventive concept;

FIG. 17 is a layout showing a part of a semiconductor device in accordance with embodiments of the inventive concept;

FIG. 18 is a part of a cross-sectional view taken along line V-V′ of FIG. 17 for describing a semiconductor device in accordance with embodiments of the inventive concept;

FIG. 19 is a layout showing a part of a semiconductor device in accordance with embodiments of the inventive concept;

FIG. 20 is a part of a cross-sectional view taken along line VI-VI′ of FIG. 19 for describing a semiconductor device in accordance with embodiments of the inventive concept;

FIGS. 21 and 22 are cross-sectional views for describing semiconductor devices in accordance with embodiments of the inventive concept;

FIGS. 23A and 23B are equivalent circuit diagrams showing parts of semiconductor devices in accordance with embodiments of the inventive concept; and

FIGS. 24 to 28 are perspective views and system block diagrams showing electronic apparatuses in accordance with embodiments of the inventive concept.

### DETAILED DESCRIPTION OF THE EMBODIMENTS

Various embodiments will now be described more fully with reference to the accompanying drawings in which some embodiments are shown. These inventive concepts may, however, be embodied in different forms and should not be construed as limited to the embodiments set forth herein. Rather, these embodiments are provided so that this disclosure is thorough and complete and fully conveys the inventive concept to those skilled in the art. In the drawings, the sizes and relative sizes of layers and regions may be exaggerated for clarity.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements. Other words used to describe relationships between elements should be interpreted in a like fashion (i.e., “between” versus “directly between,” “adjacent” versus “directly adjacent,” etc.).

It will be understood that, although the terms first, second, A, B, etc. may be used herein in reference to elements of the invention, such elements should not be construed as limited by these terms. For example, a first element could be termed a second element, and a second element could be termed a first element, without departing from the scope of the present invention. Herein, the term “and/or” includes any and all combinations of one or more referents.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein to describe embodiments of the invention is not intended to limit the scope of the invention. The articles “a,” “an,” and “the” are singular in that they have a single referent, however the use of the singular form in the present document should not preclude the presence of more than one referent. In other words, elements of the invention referred to in the singular may number one or more, unless the context clearly indicates otherwise. It will be further understood that the terms “comprises,” “comprising,” “includes,” and/or “including,” when used herein, specify the presence of stated features, items, steps, operations, elements, and/or components, but do not preclude the presence or addition of one or more other features, items, steps, operations, elements, components, and/or groups thereof.

Embodiments are described herein with reference to cross-sectional illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein are to be interpreted as is customary in the art to which this invention belongs. It will be further understood that terms in common usage should also be interpreted as is customary in the relevant art and not in an idealized or overly formal sense unless expressly so defined herein.

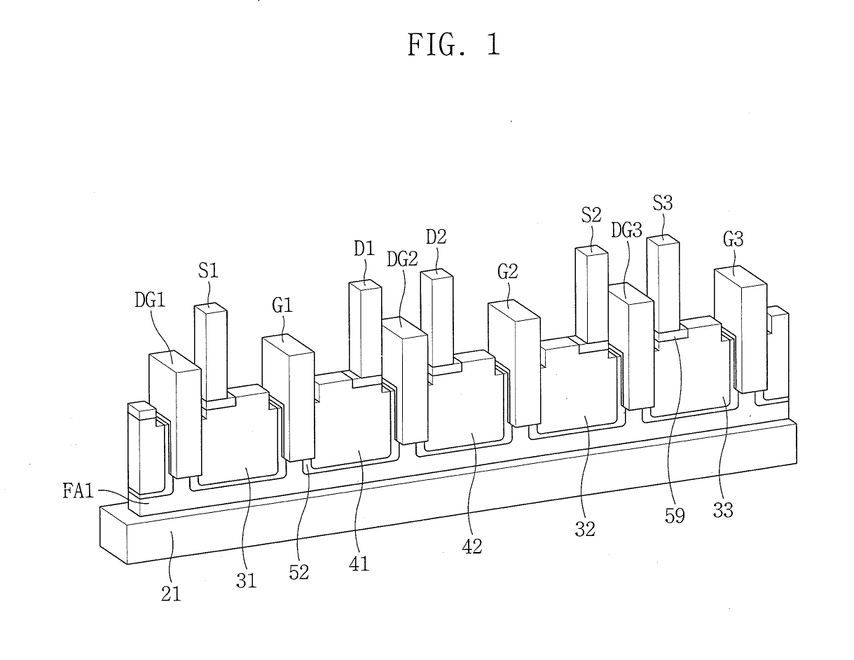

FIG. 1 is a perspective view for describing semiconductor devices in accordance with embodiments of the inventive concept, and FIG. 2 is an explosive perspective view of FIG. 1.

Referring to FIGS. 1 and 2, a fin-shaped first active region FA1 may be defined on a semiconductor substrate 21. Source regions 31, 32, and 33 and drain regions 41 and 42 spaced apart from each other may be formed in the first active region FA1. A plurality of lightly doped drains (LDDs) 52 spaced apart from each other may be formed in the first active region FA1. A metal silicide layer 59 may be formed on the source regions 31, 32, and 33 and drain regions 41 and 42. Gate electrodes G1, G2, and G3 and dummy gate electrodes DG1, DG2, and DG3 crossing the first active region FA1 may be formed. A gate dielectric layer 53 may be formed between the gate electrodes G1, G2, and G3 and dummy gate electrodes DG1, DG2, and DG3 and the first active region FA1. Drain plugs D1 and D2 and source plugs S1, S2, and S3 may be formed on the metal silicide layer 59.

The dummy gate electrodes DG1, DG2, and DG3 and the gate electrodes G1, G2, and G3 may be alternately arranged. Each of the dummy gate electrodes DG1, DG2, and DG3 and the gate electrodes G1, G2, and G3 may cover side and upper surfaces of the first active region FA1. The metal silicide layer 59 may be relatively close to the dummy gate electrodes DG1, DG2, and DG3, and relatively far from the gate electrodes G1, G2, and G3. Each of the drain plugs D1 and D2 and the source plugs S1, S2, and S3 may be relatively close to the dummy gate electrodes DG1, DG2, and DG3, and relatively far from the gate electrodes G1, G2, and G3. The drain plugs D1 and D2 and the source plugs S1, S2, and S3 may be self-aligned with side surfaces of the dummy gate electrodes DG1, DG2, and DG3.

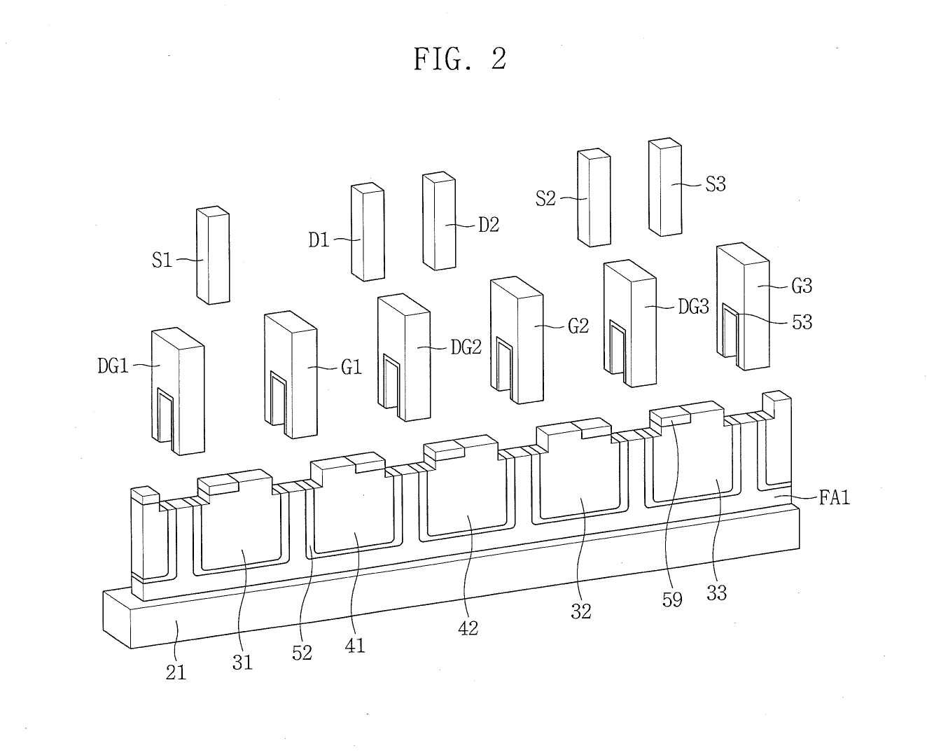

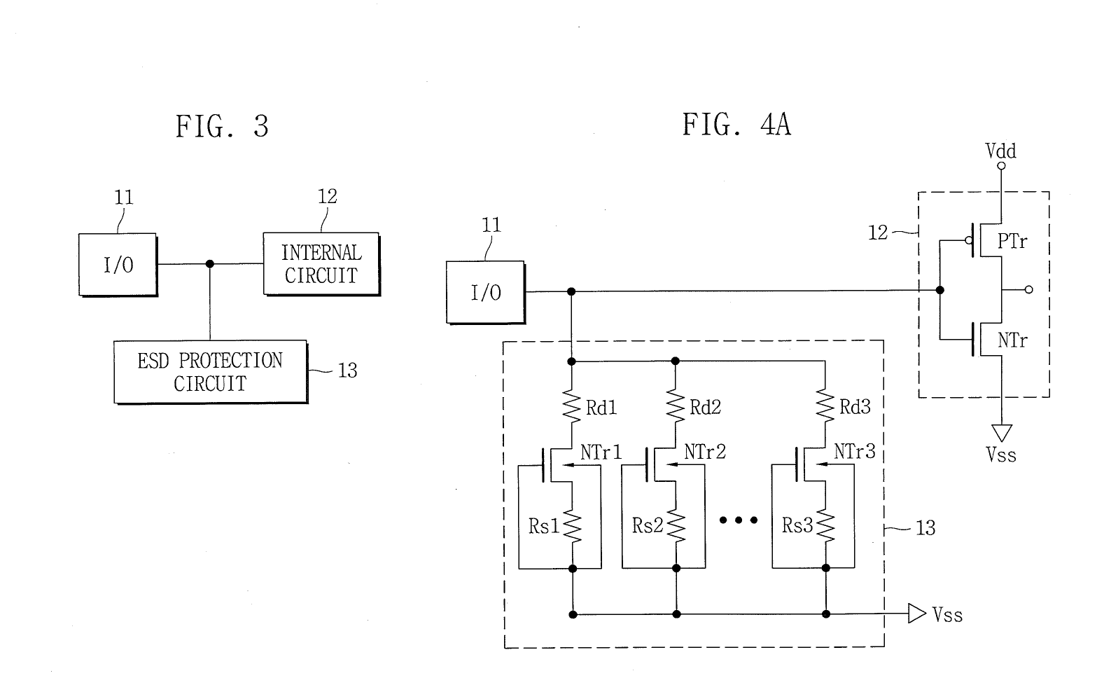

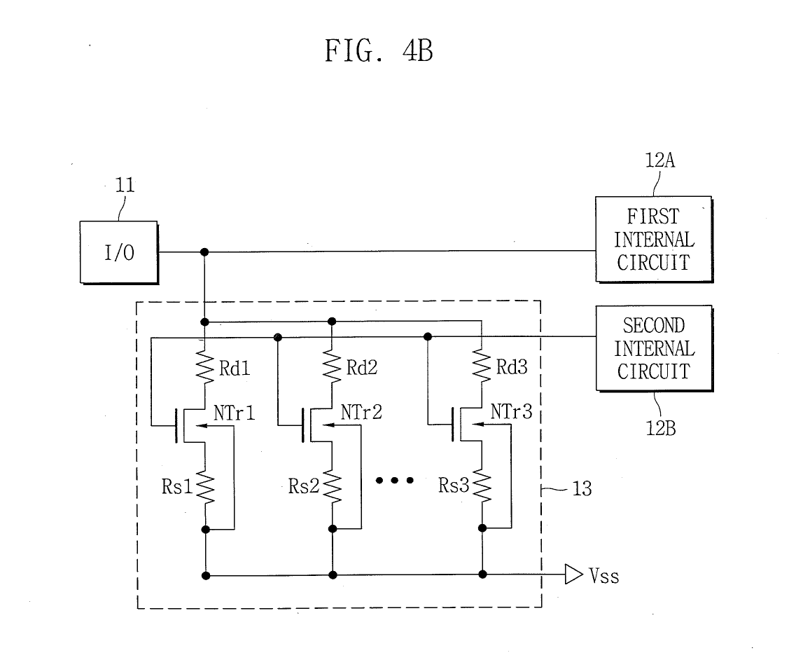

FIG. 3 is a schematic block diagram showing a part of a semiconductor device in accordance with embodiments of the inventive concept, and FIGS. 4A and 4B are equivalent circuit diagrams.

Referring to FIG. 3, an ESD protection circuit 13 may be connected to between an input/output pad 11 and an internal circuit 12. Data may be input to or output from the internal circuit 12 through the input/output pad 11. When an abnormal signal, such as an electronic discharge, is input through the input/output pad 11, the ESD protection circuit 13 may function to prevent damage to the internal circuit 12. A semiconductor device including the ESD protection circuit 13 may be interpreted as an ESD protection device.

Referring to FIG. 4A, the ESD protection circuit 13 may include a plurality of NMOS transistors NTr1, NTr2, and NTr3. Drains of the NMOS transistors NTr1, NTr2, and NTr3 may be connected to the input/output pad 11 via drain resistors Rd1, Rd2, and Rd3. Sources of the NMOS transistors NTr1, NTr2, and NTr3 may be connected to a ground (Vss) via source resistors Rs1, Rs2, and Rs3. Gates of the NMOS transistors NTr1, NTr2, and NTr3 may be connected to the ground (Vss). Bodies of the NMOS transistors NTr1, NTr2, and NTr3 may be connected to the ground (Vss).

The internal circuit 12 may include a plurality of active/passive devices, such as an NMOS transistor NTr and a PMOS transistor PTr. For example, gates of the PMOS transistor PTr and NMOS transistor NTr may be connected to the input/output pad 11. A drain of the PMOS transistor PTr may be connected to a power supply (Vdd), and a source of the PMOS transistor PTr may be connected to a drain of the NMOS transistor NTr. A source of the NMOS transistor NTr may be connected to the ground (Vss).

In other embodiments, the input/output pad 11 may be connected to the drain of the PMOS transistor PTr or the NMOS transistor NTr.

Referring to FIG. 4B, an ESD protection circuit 13 may be connected to between an input/output pad 11 and a first internal circuit 12A. The ESD protection circuit 13 may include a plurality of NMOS transistors NTr1, NTr2, and NTr3. Drains of the NMOS transistors NTr1, NTr2, and NTr3 may be connected to the input/output pad 11 via drain resistors Rd1, Rd2, and Rd3. Sources of the NMOS transistors NTr1, NTr2, and NTr3 may be connected to a ground (Vss) via source resistors Rs1, Rs2, and Rs3. Gates of the NMOS transistors NTr1, NTr2, and NTr3 may be connected to a second internal circuit 12B. Bodies of the NMOS transistors NTr1, NTr2, and NTr3 may be connected to the ground (Vss).

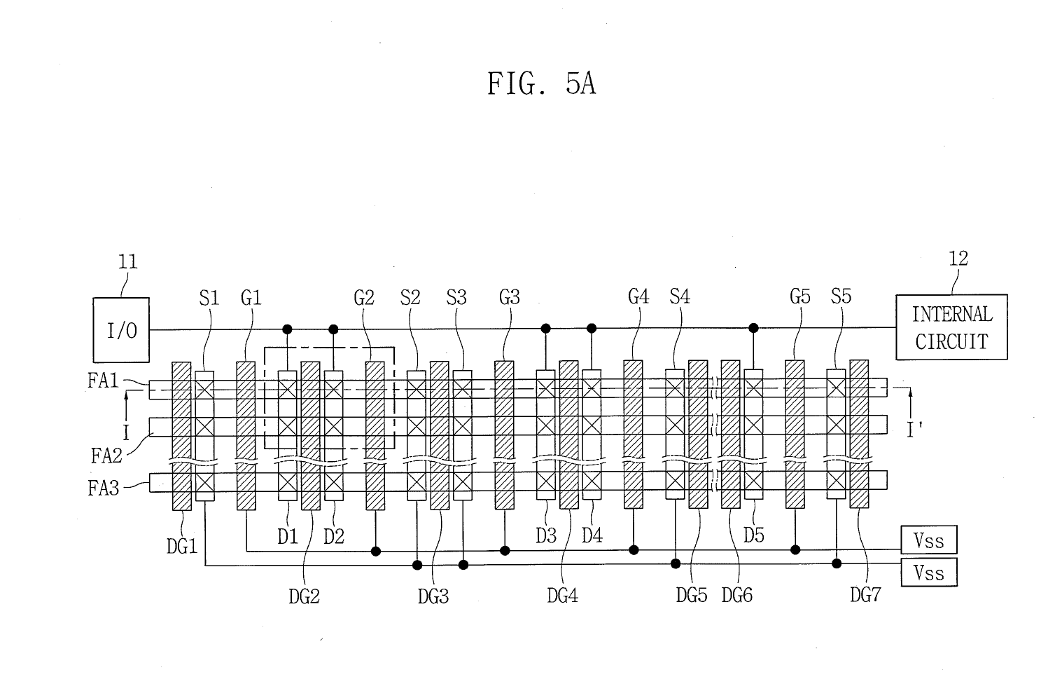

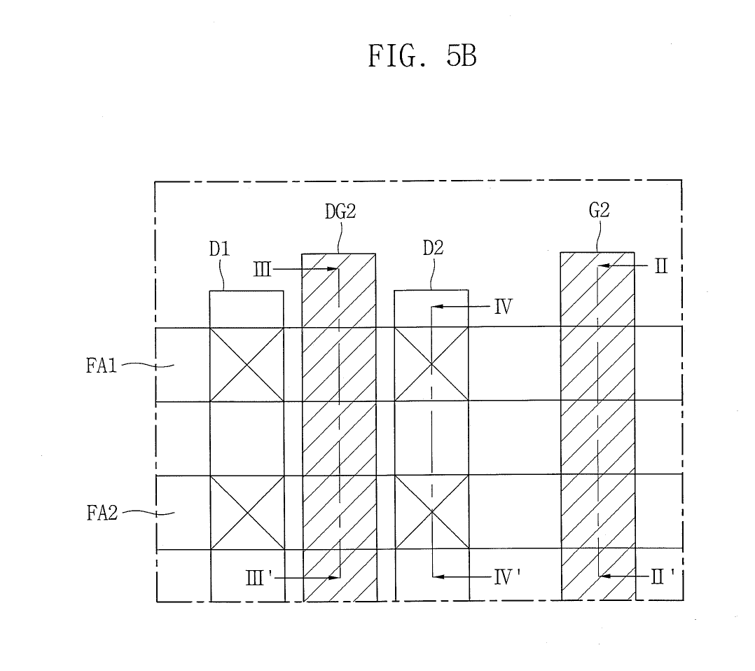

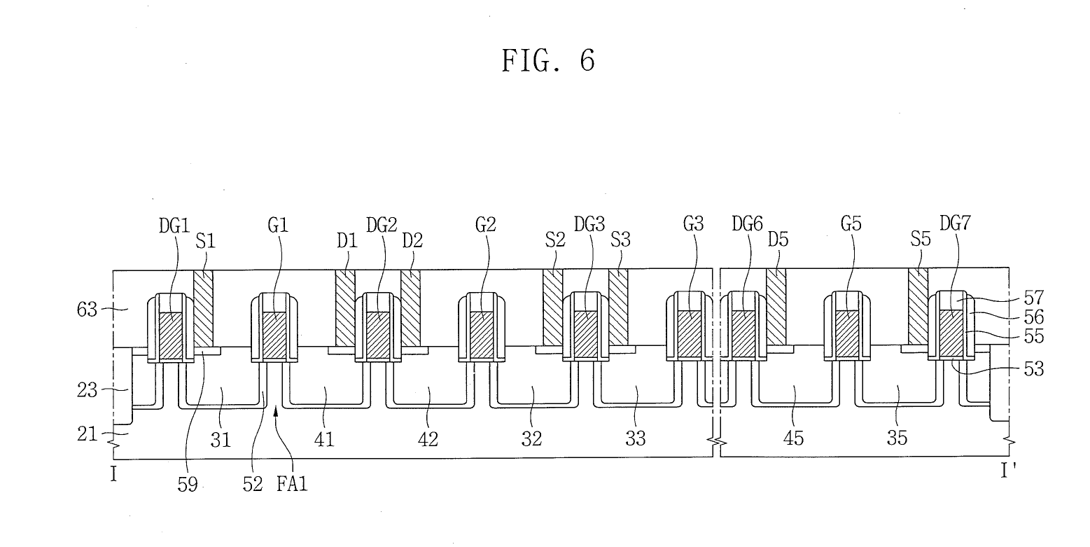

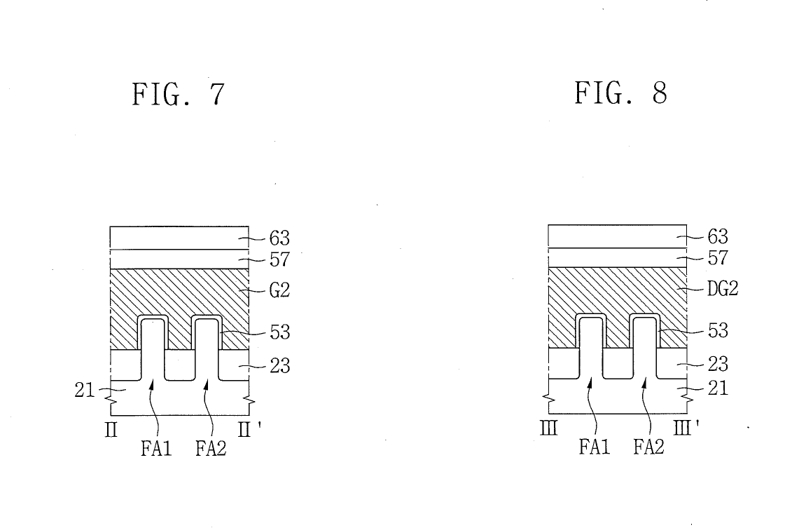

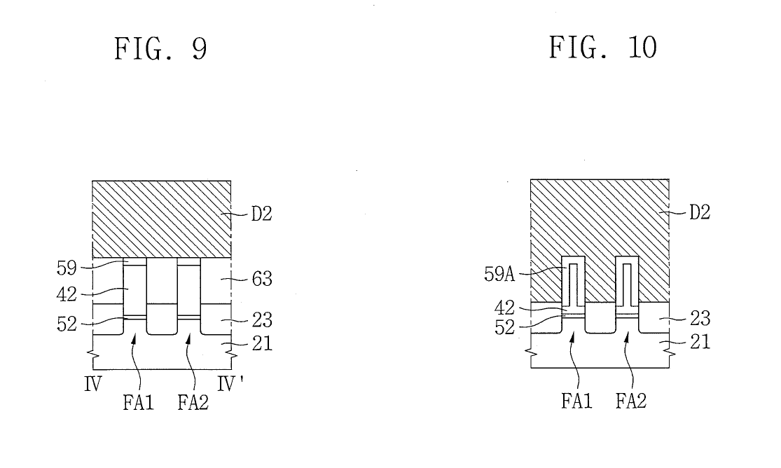

FIG. 5A is a layout showing a part of a semiconductor device in accordance with embodiments of the inventive concept, and FIG. 5B is an enlarged view showing a part of FIG. 5A in detail. FIG. 6 is a part of a cross-sectional view taken along line I-I′ of FIG. 5A for describing a semiconductor device in accordance with embodiments of the inventive concept, and FIG. 7 is a cross-sectional view taken along line II-II′ of FIG. 5B. FIG. 8 is a cross-sectional view taken along line of FIG. 5B, and FIG. 9 is a cross-sectional view taken along line IV-IV′ of FIG. 5B.

Referring to FIG. 5A, first to third active regions FA1, FA2, and FA3 in parallel may be defined. First to fifth gate electrodes G1, G2, G3, G4, and G5, and first to seventh dummy gate electrodes DG1, DG2, DG3, DG4, DG5, DG6, and DG7 crossing the first to third active regions FA1, FA2, and FA3 may be defined. First to fifth drain plugs D1, D2, D3, D4, and D5, and first to fifth source plugs S1, S2, S3, S4, and S5 close to the first to seventh dummy gate electrodes DG1, DG2, DG3, DG4, DG5, DG6, and DG7 may be formed. The first to fifth drain plugs D1, D2, D3, D4, and D5 may be connected to between the input/output pad 11 and the internal circuit 12. The first to fifth source plugs S1, S2, S3, S4, and S5, and the first to fifth gate electrodes G1, G2, G3, G4, and G5 may be connected to a ground (Vss). The first to seventh dummy gate electrodes DG1, DG2, DG3, DG4, DG5, DG6, and DG7 may be floated.

Another plurality of active regions may be additionally formed between the second active region FA2 and the third active region FA3. In addition, another plurality of gate electrodes, another plurality of dummy gate electrodes, another plurality of drain plugs, and another plurality of source plugs, may be formed between the fifth dummy gate electrode DG5 and the sixth dummy gate electrode DG6. For brevity, detailed descriptions thereof will be omitted.

In other embodiments, the first to fifth gate electrodes G1, G2, G3, G4, and G5 may be connected to the second internal circuit (reference numeral 12B in FIG. 4B).

Referring to FIG. 5A to 9, a device isolation layer 23 defining the first active region FA1, the second active region FA2, and the third active region FA3 may be formed on a semiconductor substrate 21. Source regions 31, 32, 33, and 35 and drain regions 41, 42, and 45 spaced apart from each other may be formed in the first active region FA1. A plurality of LDDs 52 spaced apart from each other may be formed in the first active region FA1. The first to fifth gate electrodes G1, G2, G3, G4, and G5, and the first to seventh dummy gate electrodes DG1, DG2, DG3, DG4, DG5, DG6, and DG7 crossing the first to third active regions FA1, FA2, and FA3 may be formed. A gate dielectric layer 53 may be formed between the first to fifth gate electrodes G1, G2, G3, G4, and G5 and first to seventh dummy gate electrodes DG1, DG2, DG3, DG4, DG5, DG6, and DG7 and the first to third active regions FA1, FA2, and FA3. A capping pattern 57 may be formed on the first to fifth gate electrodes G1, G2, G3, G4, and G5, and the first to seventh dummy gate electrodes DG1, DG2, DG3, DG4, DG5, DG6, and DG7.

Inner spacers 55 and outer spacers 56 may be formed on side surfaces of the first to fifth gate electrodes G1, G2, G3, G4, and G5, the first to seventh dummy gate electrodes DG1, DG2, DG3, DG4, DG5, DG6, and DG7, and the capping pattern 57. A metal silicide layer 59 may be formed on the first to third active regions FA1, FA2, and FA3 adjacent to both sides of the first to seventh dummy gate electrodes DG1, DG2, DG3, DG4, DG5, DG6, and DG7. An interlayer insulating layer 63 covering the entire surface of the semiconductor substrate 21 may be formed. The first to fifth drain plugs D1, D2, D3, D4, and D5 and the first to fifth source plugs S1, S2, S3, S4, and S5 passing through the interlayer insulating layer 63 and connected to the metal silicide layer 59, may be formed.

The semiconductor substrate 21 may be a single crystalline silicon wafer or a silicon on insulator (SOI) wafer. The semiconductor substrate 21 may include first conductivity-type impurities. The first conductivity-type may be N-type or P-type. For example, the semiconductor substrate 21 may include P-type impurities. The semiconductor substrate 21 may be connected to a ground (Vss). The first to third active regions FA1, FA2, and FA3 may be defined in a predetermined region of the semiconductor substrate 21 using a shallow trench isolation (STI) process. The device isolation layer 23 may include silicon oxide, silicon nitride, silicon oxynitride, or a combination thereof. The first to third active regions FA1, FA2, and FA3 may include the same material as the semiconductor substrate 21. For example, the first to third active regions FA1, FA2, and FA3 may include single crystalline silicon containing P-type impurities. Each of the first to third active regions FA1, FA2, and FA3 may have a fin shape. In other embodiments, the first to third active regions FA1, FA2, and FA3 may include N-type impurities.

The gate dielectric layer 53 may include silicon oxide, silicon nitride, silicon oxynitride, a high-K dielectric layer, or a combination thereof. The first to fifth gate electrodes G1, G2, G3, G4, and G5, and the first to seventh dummy gate electrodes DG1, DG2, DG3, DG4, DG5, DG6, and DG7 may include the same material formed at the same time. The first to fifth gate electrodes G1, G2, G3, G4, and G5, and the first to seventh dummy gate electrodes DG1, DG2, DG3, DG4, DG5, DG6, and DG7 may include a conductive layer, such as a polysilicon layer, a metal silicide layer, a metal layer, a metal nitride layer, or a combination thereof. The capping pattern 57 may include an insulating material, such as silicon oxide, silicon nitride, silicon oxynitride, or a combination thereof. The first to fifth gate electrodes G1, G2, G3, G4, and G5, and the first to seventh dummy gate electrodes DG1, DG2, DG3, DG4, DG5, DG6, and DG7 may be self-aligned under the capping pattern 57. The first to fifth gate electrodes G1, G2, G3, G4, and G5, and the first to seventh dummy gate electrodes DG1, DG2, DG3, DG4, DG5, DG6, and DG7 may cover upper and side surfaces of the first active region FA1. Lower ends of the first to fifth gate electrodes G1, G2, G3, G4, and G5 and the first to seventh dummy gate electrodes DG1, DG2, DG3, DG4, DG5, DG6, and DG7 may be formed at a lower level than upper ends of the first active region FA1.

The first to seventh dummy gate electrodes DG1, DG2, DG3, DG4, DG5, DG6, and DG7, and the first to fifth gate electrodes G1, G2, G3, G4, and G5 may be alternately arranged. For example, the first gate electrode G1 may be formed between the first dummy gate electrode DG1 and the second dummy gate electrode D02. The second gate electrode G2 may be formed between the second dummy gate electrode DG2 and the third dummy gate electrode DG3. The third gate electrode G3 may be formed between the third dummy gate electrode DG3 and the fourth dummy gate electrode DG4. The fourth gate electrode G4 may be formed between the fourth dummy gate electrode DG4 and the fifth dummy gate electrode DG5. The fifth gate electrode G5 may be formed between the sixth dummy gate electrode DG6 and the seventh dummy gate electrode DG7.

The inner spacers 55 may be in contact with side surfaces of the first to fifth gate electrodes G1, G2, G3, G4, and G5, and first to seventh dummy gate electrodes DG1, DG2, DG3, DG4, DG5, DG6, and DG7. The inner spacers 55 may have an “L” shape. The outer spacers 56 may be formed on the inner spacers 55. The inner spacers 55 and the outer spacers 56 may include an insulating material, such as silicon oxide, silicon nitride, silicon oxynitride, and a combination thereof. The inner spacers 55 and the outer spacers 56 may include a different material from each other.

The LDDs 52, the source regions 31, 32, 33, and 35, and the drain regions 41, 42, and 45 may be aligned with outer sides of the first to fifth gate electrodes G1, G2, G3, G4, and G5 and the first to seventh dummy gate electrodes DG1, DG2, DG3, DG4, DG5, DG6, and DG7. The LDDs 52, the source regions 31, 32, 33, and 35, and the drain regions 41, 42, and 45 may be formed between the first to fifth gate electrodes G1, G2, G3, G4, and G5 and the first to seventh dummy gate electrodes DG1, DG2, DG3, DG4, DG5, DG6, and DG7. The LDDs 52 may cover side surfaces of the source regions 31, 32, 33, and 35 and drain regions 41, 42, and 45. The LDDs 52, the source regions 31, 32, 33, and 35, and the drain regions 41, 42, and 45 may include second conductivity-type impurities. The second conductivity-type may be N-type or P-type. For example, when the first conductivity-type is P-type, the second conductivity-type may be N-type. When the first conductivity-type is N-type, the second conductivity-type may be P-type. The LDDs 52 may include a lower concentration of the second conductivity-type impurities than the source regions 31, 32, 33, and 35 and the drain regions 41, 42, and 45.

The source regions 31, 32, 33, and 35 and the drain regions 41, 42, and 45 may include a different material from the first active region FA1. For example, the first active region FA1 may include single crystalline silicon containing P-type impurities, and the source regions 31, 32, 33, and 35 and the drain regions 41, 42, and 45 may include SiC containing N-type impurities. The source regions 31, 32, 33, and 35 and the drain regions 41, 42, and 45 may protrude at a higher level than lower ends of the first to fifth gate electrodes G1, G2, G3, G4, and G5 and first to seventh dummy gate electrodes DG1, DG2, DG3, DG4, DG5, DG6, and DG7.

For example, the first source region 31 may be formed between the first dummy gate electrode DG1 and the first gate electrode G1. The first drain region 41 may be formed between the first gate electrode G1 and the second dummy gate electrode DG2. The second drain region 42 may be formed between the second dummy gate electrode DG2 and the second gate electrode G2. The second source region 32 may be formed between the second gate electrode G2 and the third dummy gate electrode DG3. The third source region 33 may be formed between the third dummy gate electrode DG3 and the third gate electrode G3. The fifth drain region 45 may be formed between the sixth dummy gate electrode DG6 and the fifth gate electrode G5. The fifth source region 35 may be formed between the fifth gate electrode G5 and the seventh dummy gate electrode DG7.

The metal silicide layer 59 may partially cover upper surfaces of the source regions 31, 32, 33, and 35, or drain regions 41, 42, and 45. The metal silicide layer 59 may be relatively close to the first to seventh dummy gate electrodes DG1, DG2, DG3, DG4, DG5, DG6, and DG7, and relatively far from the first to fifth gate electrodes G1, G2, G3, G4, and G5. The distance between the metal silicide layer 59 and the first to fifth gate electrodes G1, G2, G3, G4, and G5 may be greater than that between the metal silicide layer 59 and the first to seventh dummy gate electrodes DG1, DG2, DG3, DG4, DG5, DG6, and DG7. The metal silicide layer 59 may be self-aligned with outer sides of the first to seventh dummy gate electrodes DG1, DG2, DG3, DG4, DG5, DG6, and DG7. The metal silicide layer 59 may be in contact with the outer spacers 56. The metal silicide layer 59 may be in contact with the source regions 31, 32, 33, and 35 or the drain regions 41, 42, and 45. The metal silicide layer 59 may include CoSi, NiSi, TiSi, TaSi, WSi, or a combination thereof.

The interlayer insulating layer 63 may include silicon oxide, silicon nitride, silicon oxynitride, or a combination thereof. The first to fifth drain plugs D1, D2, D3, D4, and D5, and the first to fifth source plugs S1, S2, S3, S4, and S5 may include a conductive layer such as a metal layer. The first to fifth drain plugs D1, D2, D3, D4, and D5, and the first to fifth source plugs S1, S2, S3, S4, and S5 may include W, WN, Ti, TiN, Ta, TaN, Cu, Al, Ru, Au, Ni, Pt, Ag, or a combination thereof.

The first to fifth drain plugs D1, D2, D3, D4, and D5, and the first to fifth source plugs S1, S2, S3, S4, and S5 may be in contact with the metal silicide layer 59. The first to fifth drain plugs D1, D2, D3, D4, and D5 and the first to fifth source plugs S1, S2, S3, S4, and S5 may be relatively close to the first to seventh dummy gate electrodes DG1, DG2, DG3, DG4, DG5, DG6, and DG7, and relatively far from the first to fifth gate electrodes G1, G2, G3, G4, and G5. The first to fifth drain plugs D1, D2, D3, D4, and D5, and the first to fifth source plugs S1, S2, S3, S4, and S5 may be self-aligned with outer sides of the first to seventh dummy gate electrodes DG1, DG2, DG3, DG4, DG5, DG6, and D07. The first to fifth drain plugs D1, D2, D3, D4, and D5, and the first to fifth source plugs S1, S2, S3, S4, and S5 may be in contact with side surfaces of the outer spacers 56.

For example, the first source plug S1 may be relatively close to the first dummy gate electrode DG1, and relatively far from the first gate electrode G1. The distance between the first source plug S1 and the first gate electrode G1 may be greater than that between the first source plug S1 and the first dummy gate electrode DG1. The first source plug S1 may be electrically connected to the first source region 31 via the metal silicide layer 59. The first drain plug D1 may be relatively close to the second dummy gate electrode DG2, and relatively far from the first gate electrode G1. The distance between the first drain plug D1 and the first gate electrode G1 may be greater than that between the first drain plug D1 and the second dummy gate electrode DG2. The first drain plug D1 may be electrically connected to the first drain region 41 via the metal silicide layer 59.

The second drain plug D2 may be relatively close to the second dummy gate electrode DG2, and relatively far from the second gate electrode G2. The distance between the second drain plug D2 and the second gate electrode G2 may be greater than that between the second drain plug D2 and the second dummy gate electrode DG2. The second drain plug D2 may be electrically connected to the second drain region 42 via the metal silicide layer 59. The second source plug S2 may be relatively close to the third dummy gate electrode DG3, and relatively far from the second gate electrode G2. The distance between the second source plug S2 and the second gate electrode G2 may be greater than that between the second source plug S2 and the third dummy gate electrode DG3. The second source plug S2 may be electrically connected to the second source region 32 via the metal silicide layer 59. The third source plug S3 may be relatively close to the third dummy gate electrode DG3, and relatively far from the third gate electrode G3. The distance between the third source plug S3 and the third gate electrode G3 may be greater than that between the third source plug S3 and the third dummy gate electrode DG3. The third source plug S3 may be electrically connected to the third source region 33 via the metal silicide layer 59.

The fifth drain plug D5 may be relatively close to the sixth dummy gate electrode DG6, and relatively far from the fifth gate electrode G5. The fifth drain plug D5 may be electrically connected to the fifth drain region 45 via the metal silicide layer 59. The fifth source plug S5 may be relatively close to the seventh dummy gate electrode DG7, and relatively far from the fifth gate electrode G5. The fifth source plug S5 may be electrically connected to the fifth source region 35 via the metal silicide layer 59.

FIGS. 10 to 16 are cross-sectional views for describing semiconductor devices in accordance with embodiments of the inventive concept.

Referring to FIG. 10, the second drain plug D2 may cover side and upper surfaces of the first and second active regions FA1 and FA2. The metal silicide layer 59A may be formed on side and upper surfaces of the second drain region 42. For example, the second drain plug D2 may cover the side and upper surfaces of the second drain region 42. The second drain plug D2 may be in contact with the metal silicide layer 59A. A lower end of the second drain plug D2 may be formed at a lower level than an upper end of the second drain region 42, and at a higher level than a lower end of the second drain region 42.

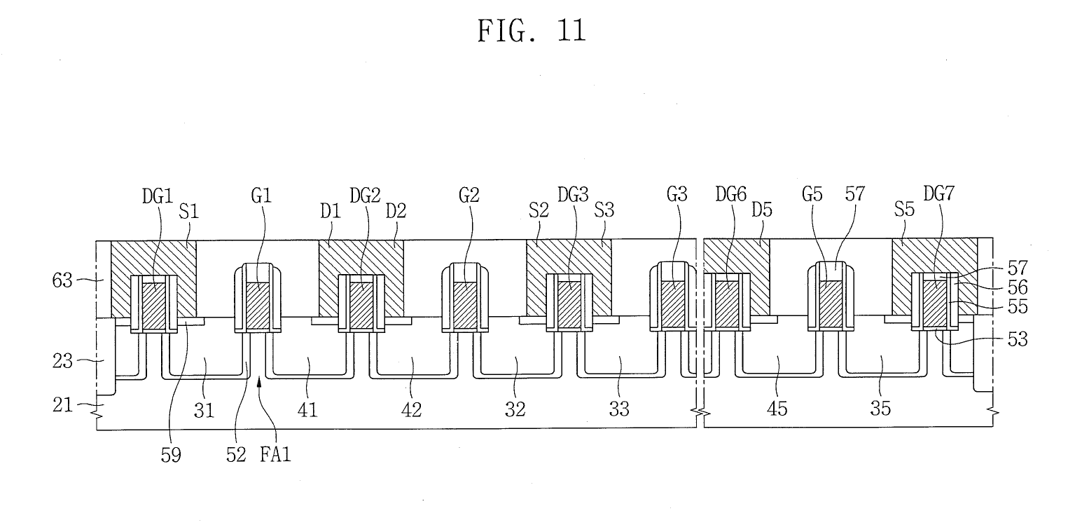

Referring to FIG. 11, the first drain plug D1 and the second drain plug D2 may be connected to each other. The first drain plug D1 and the second drain plug D2 may cover the second dummy gate electrode DG2. The second source plug S2 and the third source plug S3 may be connected to each other. The second source plug S2 and the third source plug S3 may cover the third dummy gate electrode DG3. The capping pattern 57 may remain between the first to fifth drain plugs D1, D2, D3, D4, and D5 and first to fifth source plugs S1, S2, S3, S4, and S5 and the first to seventh dummy gate electrodes DG1, DG2, DG3, DG4, DG5, DG6, and DG7.

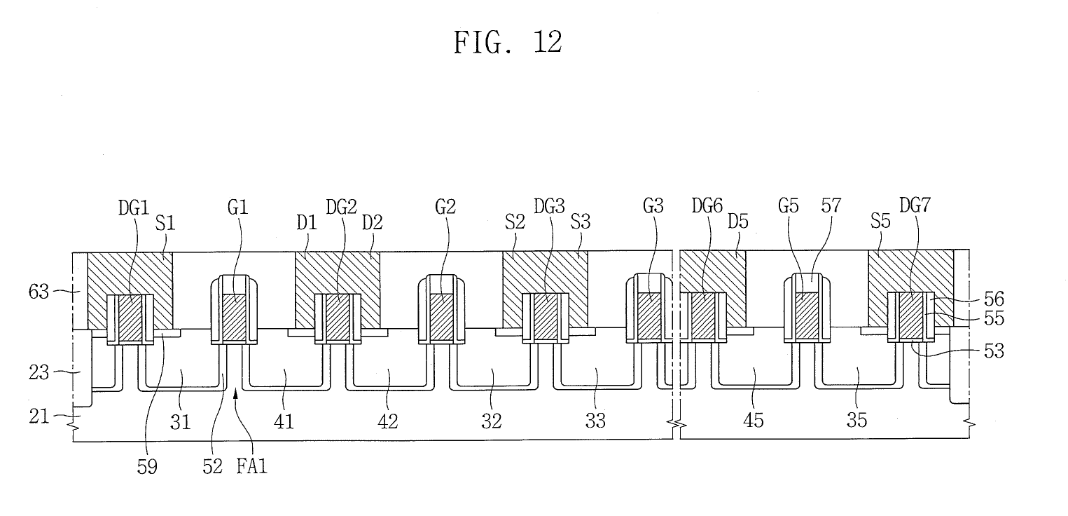

Referring to FIG. 12, the first to fifth drain plugs D1, D2, D3, D4, and D5, and the first to fifth source plugs S1, S2, S3, S4, and S5 may be in contact with the first to seventh dummy gate electrodes DG1, DG2, DG3, DG4, DG5, DG6, and DG7.

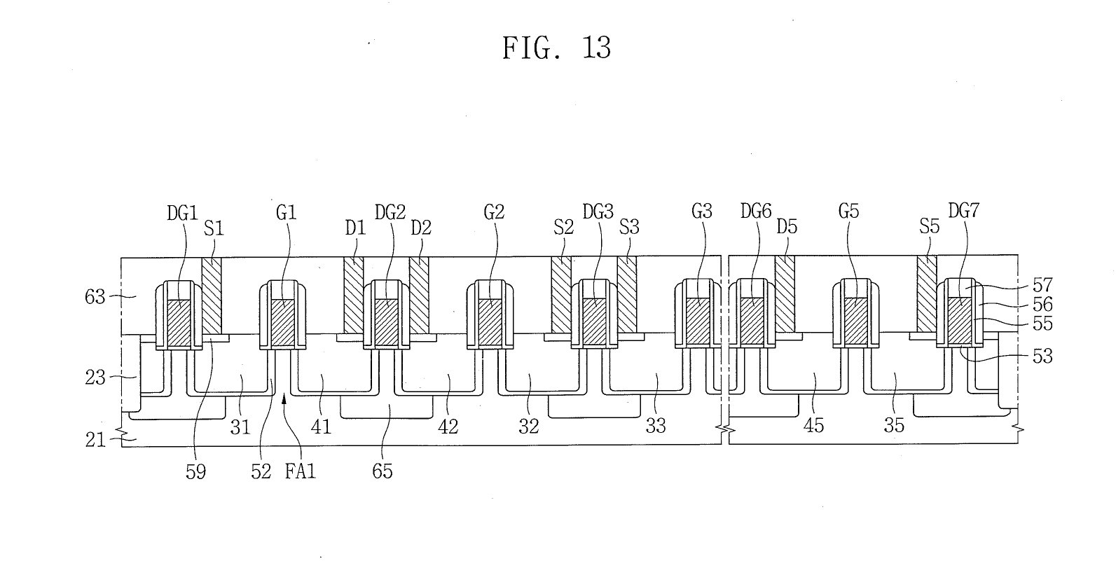

Referring to FIG. 13, the first active region FA1 may include a plurality of wells 65. The wells 65 may include the second conductivity-type impurities. The wells 65 may be arranged under the first to seventh dummy gate electrodes DG1, DG2, DG3, DG4, DG5, DG6, and DG7. The wells 65 may be formed between the source regions 31, 32, 33, and 35 and the drain regions 41, 42, and 45. The wells 65 may be in direct contact with the LDDs 52. Lower ends of the wells 65 may be formed at a lower level than the source regions 31, 32, 33, and 35 and the drain regions 41, 42, and 45.

In other embodiments, the LDDs 52 may be partially omitted. The wells 65 may be in direct contact with the source regions 31, 32, 33, and 35, or the drain regions 41, 42, and 45.

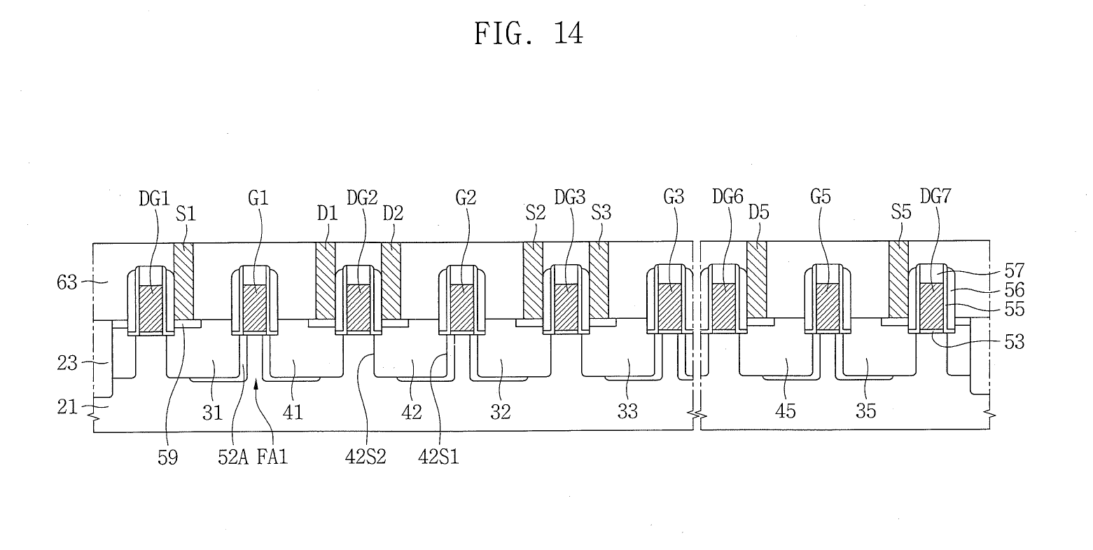

Referring to FIG. 14, LDDs 52A may be arranged close to bottoms of the first to fifth gate electrodes G1, G2, G3, G4, and G5. The LDDs 52A may be omitted under the first to seventh dummy gate electrodes DG1, DG2, DG3, DG4, DG5, DG6, and DG7. For example, the second drain region 42 may include a first side surface 42S1 and a second side surface 42S2. The first side surface 42S1 may be close to a side surface of the second gate electrode G2. The second side surface 42S2 may be close to a side surface of the second dummy gate electrode DG2. The first side surface 42S1 of the second drain region 42 may be in contact with one of the LDDs 52A. The second side surface 42S2 of the second drain region 42 may be in direct contact with the first active region FA1.

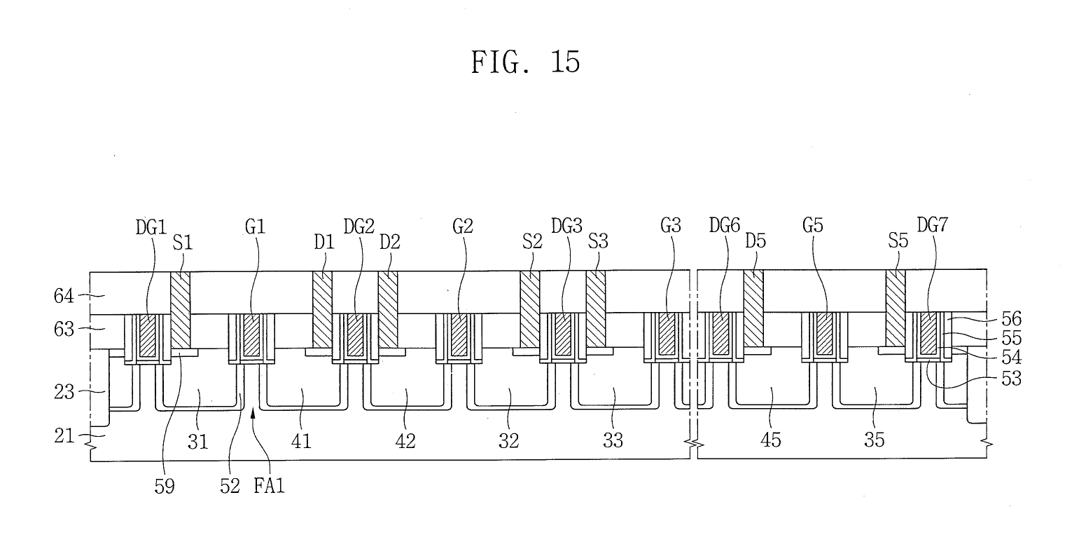

Referring to FIG. 15, each of the first to fifth gate electrodes G1, G2, G3, G4, and G5 and first to seventh dummy gate electrodes DG1, DG2, DG3, DG4, DG5, DG6, and DG7 may include a replacement gate electrode. A first gate dielectric layer 53 and a second gate dielectric layer 54 may be formed. A first interlayer insulating layer 63, and a second interlayer insulating layer 64 disposed on the first interlayer insulating layer 63 may be formed.

The second gate dielectric layer 54 may surround bottom and side surfaces of the first to fifth gate electrodes G1, G2, G3, G4, and G5 and first to seventh dummy gate electrodes DG1, DG2, DG3, DG4, DG5, DG6, and DG7. The second gate dielectric layer 54 may be in direct contact with the bottom and side surfaces of the first to fifth gate electrodes G1, G2, G3, G4, and G5 and first to seventh dummy gate electrodes DG1, DG2, DG3, DG4, DG5, DG6, and D07. The second gate dielectric layer 54 may be interposed between the first to fifth gate electrodes G1, G2, G3, G4, and G5 and first to seventh dummy gate electrodes DG1, DG2, DG3, DG4, DG5, DG6, and DG7 and the inner spacers 55, and the second gate dielectric layer 54 may be interposed between the first to fifth gate electrodes G1, G2, G3, G4, and G5 and first to seventh dummy gate electrodes DG1, DG2, DG3, DG4, DG5, DG6, and DG7 and the first gate dielectric layer 53.

The first gate dielectric layer 53 may be formed between the first active region FA1 and the second gate dielectric layer 54. The first gate dielectric layer 53 may be referred to as an interfacial oxide layer. The first gate dielectric layer 53 may be formed using a cleaning process. The first gate dielectric layer 53 may include silicon oxide. The second gate dielectric layer 54 may include silicon oxide, silicon nitride, silicon oxynitride, High-K dielectric layer, or a combination thereof.

The first interlayer insulating layer 63 and the second interlayer insulating layer 64 may include silicon oxide, silicon nitride, silicon oxynitride, or a combination thereof. Upper ends of the first interlayer insulating layer 63, the first to fifth gate electrodes G1, G2, G3, G4, and G5, and the first to seventh dummy gate electrodes DG1, DG2, DG3, DG4, DG5, DG6, and DG7 may be formed substantially on the same plane.

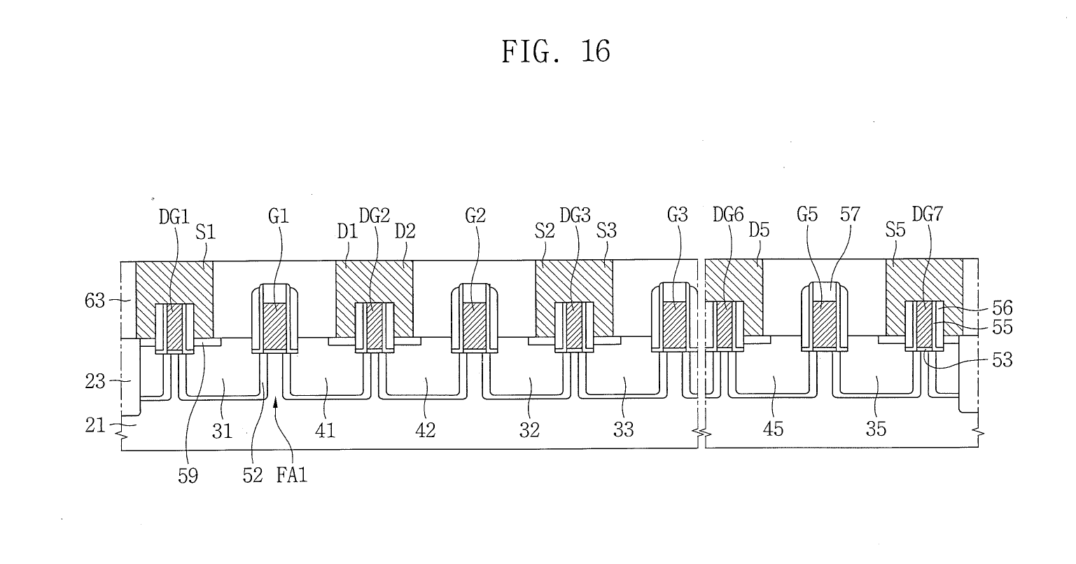

Referring to FIG. 16, the horizontal distance of the first to seventh dummy gate electrodes DG1, DG2, DG3, DG4, DG5, DG6, and DG7 may be smaller than that of the first to fifth gate electrodes G1, G2, G3, G4, and G5.

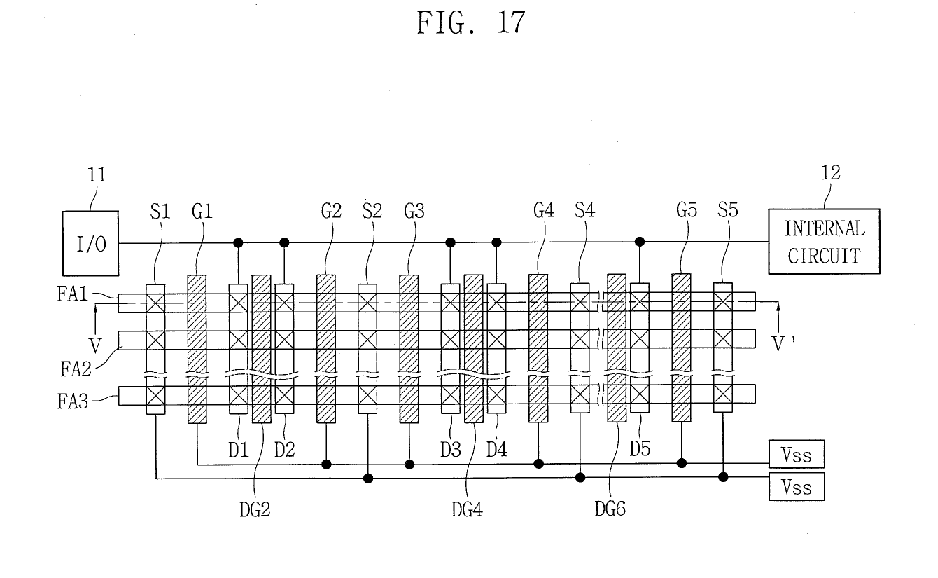

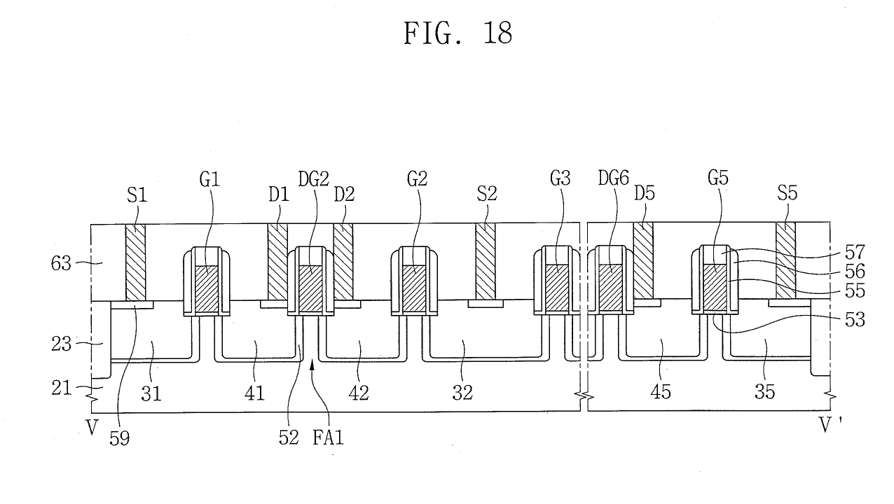

FIG. 17 is a layout showing a part of a semiconductor device in accordance with embodiments of the inventive concept, and FIG. 18 is a part of a cross-sectional view taken along line V-V′ of FIG. 17.

Referring to FIG. 17, first to third active regions FA1, FA2, and FA3 in parallel may be defined. First to fifth gate electrodes G1, G2, G3, G4, and G5, a second dummy gate electrode DG2, a fourth dummy gate electrode DG4, and a sixth dummy gate electrode DG6 crossing the first to third active regions FA1, FA2, and FA3 may be formed. First to fifth drain plugs D1, D2, D3, D4, and D5, a first source plug S1, a second source plug S2, a fourth source plug S4, and a fifth source plug S5 may be formed. The first and second drain plugs D1 and D2 may be close to the second dummy gate electrode DG2, the third and fourth drain plugs D3 and D4 may be close to the fourth dummy gate electrode DG4, and the fifth drain plug D5 may be close to the sixth dummy gate electrode DG6. The first to fifth drain plugs D1, D2, D3, D4, and D5 may be connected to between an input/output pad 11 and an internal circuit 12.

The first gate electrode G1 may be formed between the first source plug S1 and the first drain plug D1. The second source plug S2 may be formed between the second and third gate electrodes G2 and G3. The fourth gate electrode G4 may be formed between the fourth drain plug D4 and the fourth source plug S4. The fifth gate electrode G5 may be formed between the fifth drain plug D5 and the fifth source plug S5. The first source plug S1, the second source plug S2, the fourth source plug S4, the fifth source plug S5, and the first to fifth gate electrodes G1, G2, G3, G4, and G5 may be connected to a ground (Vss).

Referring to FIGS. 17 and 18, a device isolation layer 23 defining the first active region FA1, the second active region FA2, and the third active region FA3 in parallel, may be formed on a semiconductor substrate 21. Source regions 31, 32, and 35 and drain regions 41, 42, and 45 spaced apart from each other may be formed in the first active region FA1. A plurality of lightly doped drains (LDDs) 52 spaced apart from each other may be formed in the first active region FA1. The first to fifth gate electrodes G1, G2, G3, G4, and G5, the second dummy gate electrode DG2, the fourth dummy gate electrode DG4, and the sixth dummy gate electrode DG6 crossing the first to third active regions FA1, FA2, and FA3 may be formed. A gate dielectric layer 53 may be formed between the first to fifth gate electrodes G1, G2, G3, G4, and G5, second dummy gate electrode DG2, fourth dummy gate electrode DG4, and sixth dummy gate electrode DG6, and the first to third active regions FA1, FA2, and FA3. A capping pattern 57 may be formed on the first to fifth gate electrodes G1, G2, G3, G4, and G5, the second dummy gate electrode DG2, the fourth dummy gate electrode DG4, and the sixth dummy gate electrode DG6.

Inner spacers 55 and outer spacers 56 may be sequentially formed on side surfaces of the first to fifth gate electrodes G1, G2, G3, G4, and G5, second dummy gate electrode DG2, fourth dummy gate electrode DG4, sixth dummy gate electrode DG6, and capping pattern 57. A metal silicide layer 59 may be partially formed on the source regions 31, 32, and 35 and the drain regions 41, 42, and 45. An interlayer insulating layer 63 covering the entire surface of the semiconductor substrate 21 may be formed. The first to fifth drain plugs D1, D2, D3, D4, and D5, the first source plug S1, the second source plug S2, the fourth source plug S4, and the fifth source plug S5 passing through the interlayer insulating layer 63 and connected to the metal silicide layer 59 may be formed.

The first drain plug D1 may be relatively close to the second dummy gate electrode DG2, and relatively far from the first gate electrode G1. The first drain plug D1 may be electrically connected to the first drain region 41 via the metal silicide layer 59. The second drain plug D2 may be relatively close to the second dummy gate electrode DG2, and relatively far from the second gate electrode G2. The second drain plug D2 may be electrically connected to the second drain region 42 via the metal silicide layer 59.

The distance between the first source plug S1 and the first gate electrode G1 may be substantially the same as that between the first drain plug D1 and the first gate electrode G1. The first source plug S1 may be electrically connected to the first source region 31 via the metal silicide layer 59. The second source plug S2 may be formed between the second gate electrode G2 and the third gate electrode G3. The distance between the second source plug S2 and the second gate electrode G2 may be substantially the same as that between the second drain plug D2 and the second gate electrode G2. The second source region 32 may be formed between the second gate electrode G2 and the third gate electrode G3. The second source plug S2 may be electrically connected to the second source region 32 via the metal silicide layer 59.

The fifth drain plug D5 may be relatively close to the sixth dummy gate electrode DG6, and relatively far from the fifth gate electrode G5. The fifth drain plug D5 may be electrically connected to the fifth drain region 45 via the metal silicide layer 59. The distance between the fifth source plug S5 and the fifth gate electrode G5 may be substantially the same as that between the fifth drain plug D5 and the fifth gate electrode G5. The fifth source plug S5 may be electrically connected to the fifth source region 35 via the metal silicide layer 59,

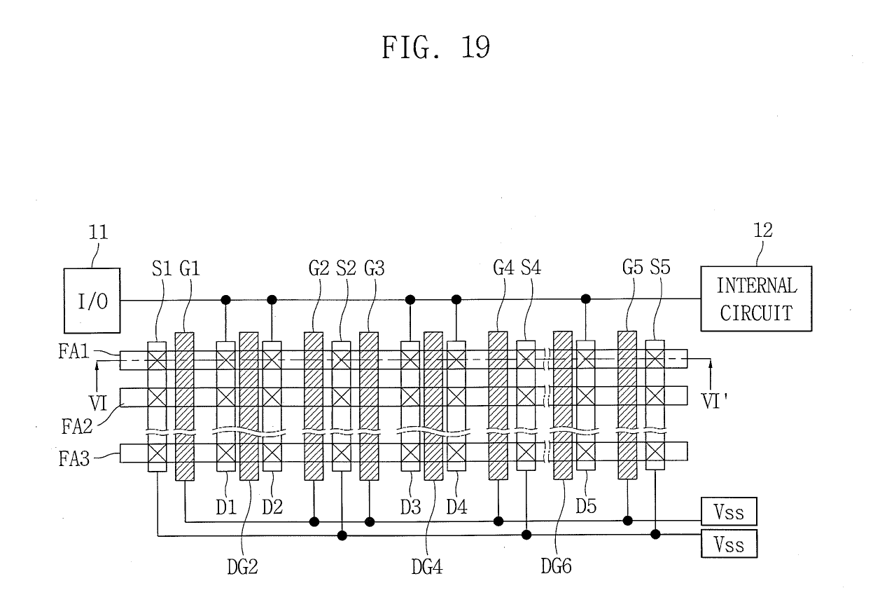

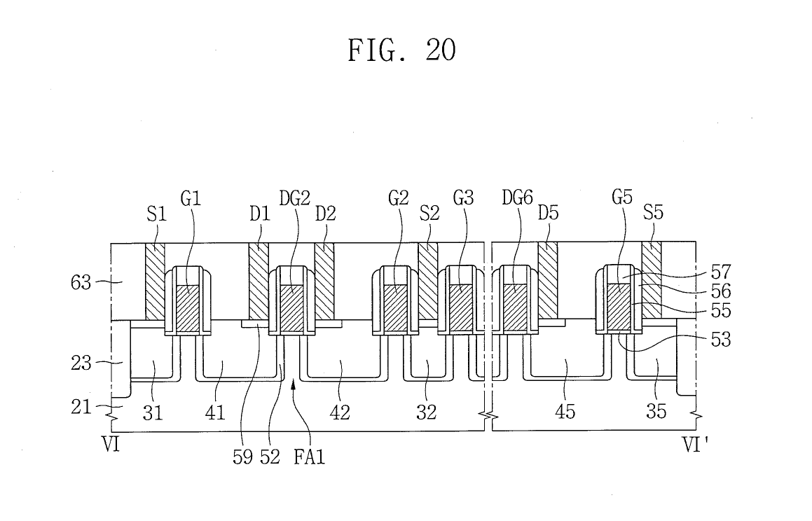

FIG. 19 is a layout showing a part of a semiconductor device in accordance with embodiments of the inventive concept, and FIG. 20 is a part of a cross-sectional view taken along line VI-VI′ of FIG. 17.

Referring to FIG. 19, first to third active regions FA1, FA2, and FA3 in parallel may be defined. First to fifth gate electrodes G1, G2, G3, G4, and G5, a second dummy gate electrode DG2, a fourth dummy gate electrode DG4, and a sixth dummy gate electrode DG6 that cross the first to third active regions FA1, FA2, and FA3 may be formed. First to fifth drain plugs D1, D2, D3, D4, and D5, a first source plug S1, a second source plug S2, a fourth source plug S4, and a fifth source plug S5 may be formed. The first and second drain plugs D1 and D2 may be close to the second dummy gate electrode DG2, the third and fourth drain plugs D3 and D4 may be close to the fourth dummy gate electrode DG4, and the fifth drain plug D5 may be close to the sixth dummy gate electrode DG6. The first to fifth drain plugs D1, D2, D3, D4, and D5 may be connected to between an input/output pad 11 and an internal circuit 12.

The first source plug S1 may be close to the first gate electrode G1. The second source plug S2 may be formed between the second and third gate electrodes G2 and G3. The second source plug S2 may be close to the second and third gate electrodes G2 and G3. The fourth source plug S4 may be close to the fourth gate electrode G4. The fifth source plug S5 may be close to the fifth gate electrode G5. The first source plug S1, the second source plug S2, the fourth source plug S4, the fifth source plug S5, and the first to fifth gate electrodes G1, G2, G3, G4, and G5 may be connected to a ground (Vss).

Referring to FIGS. 19 and 20, the first source plug S1 may be self-aligned with the first gate electrode G1. The second source plug S2 may be self-aligned between the second gate electrode G2 and the third gate electrode G3. The horizontal distance between the second gate electrode G2 and the third gate electrode G3 may be smaller than that between the second dummy gate electrode DG2 and the second gate electrode G2. The fifth source plug S5 may be self-aligned with the fifth gate electrode G5.

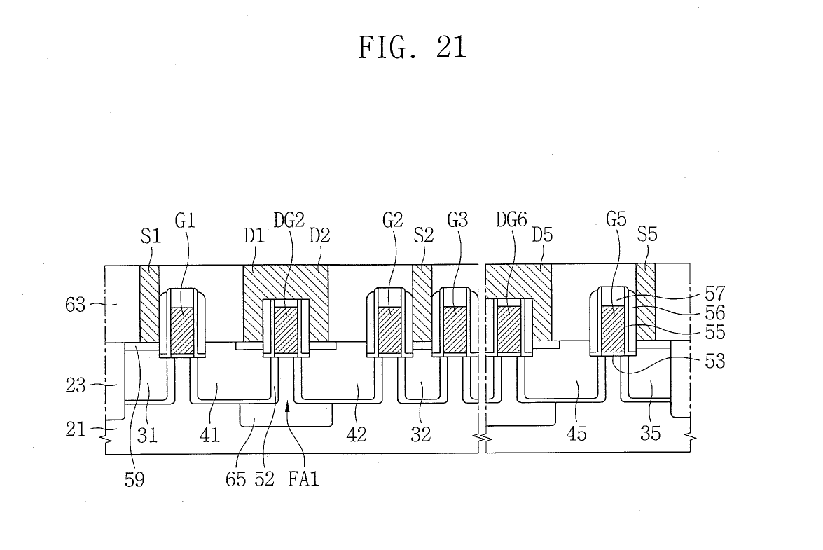

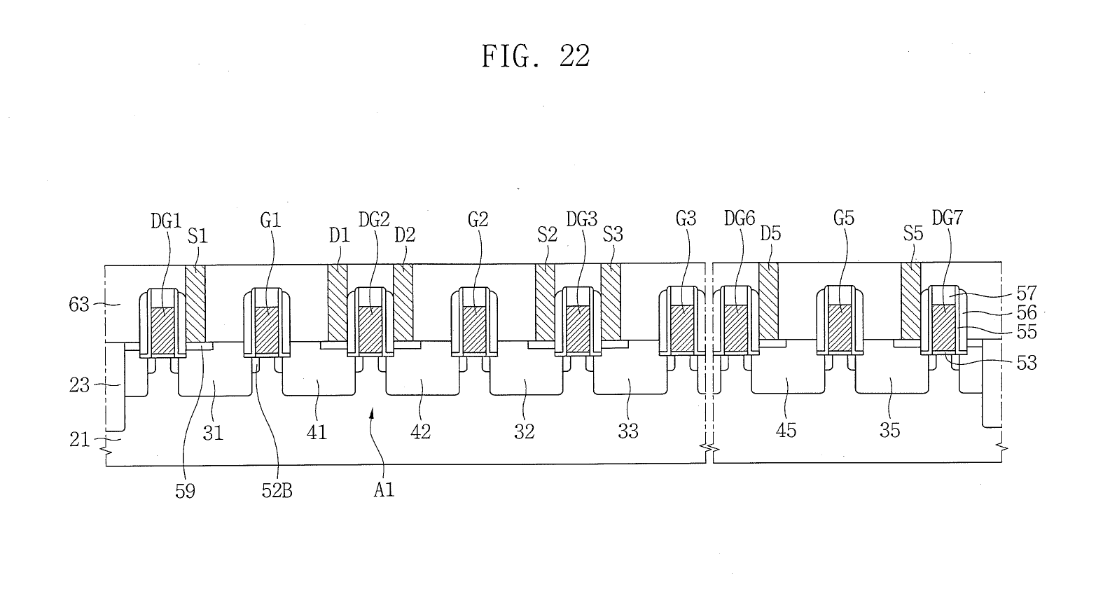

FIGS. 21 and 22 are cross-sectional views for describing semiconductor devices in accordance with embodiments of the inventive concept.

Referring to FIG. 21, a first active region FA1 may include a plurality of wells 65. The wells 65 may include the second conductivity-type impurities. For example, one selected from the wells 65 may be arranged under the second dummy gate electrode DG2 and the sixth dummy gate electrode DG6. A first drain plug D1 and a second drain plug D2 may cover the second dummy gate electrode DG2.

Referring to FIG. 22, an active region A1, a device isolation layer 23, source regions 31, 32, 33, and 35, drain regions 41, 42, and 45, LDDs 52B, a gate dielectric layer 53, gate electrodes G1, G2, G3, and G5, dummy gate electrodes DG1, DG2, DG3, DG6, and DG7, a capping pattern 57, inner spacers 55, outer spacers 56, a metal silicide layer 59, drain plugs D1, D2, and D5, source plugs S1, S2, S3, and S5, and an interlayer insulating layer 63 may be formed on a semiconductor substrate 21. The active region A1, the source regions 31, 32, 33, and 35, the drain regions 41, 42, and 45, and the gate electrodes G1, G2, G3, and G5 may configure planar transistors.

In still other embodiments, the semiconductor devices in accordance with embodiments of the inventive concept may be applied to various structures, such as a nano-wire transistor, a vertical transistor, and a recessed transistor.

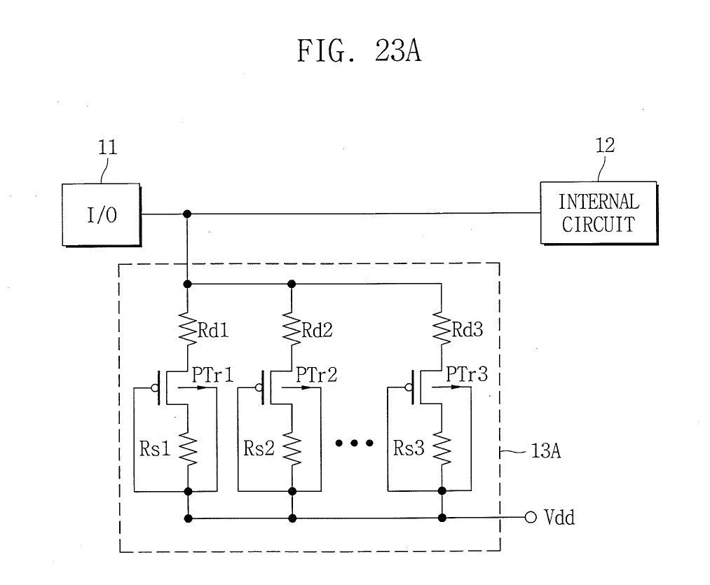

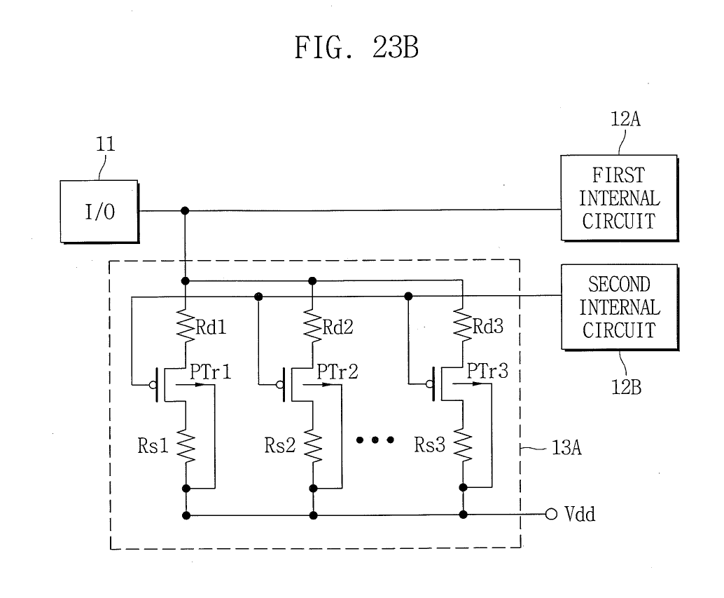

FIGS. 23A and 23B are equivalent circuit diagrams showing a part of semiconductor devices in accordance with embodiments of the inventive concept.

Referring to FIG. 23A, an ESD protection circuit 13A may include a plurality of PMOS transistors PTr1, PTr2, and PTr3. Drains of the PMOS transistors PTr1, PTr2, and PTr3 may be connected to an input/output pad 11 via drain resistors Rd1, Rd2, and Rd3. Sources of the PMOS transistors PTr1, PTr2, and PTr3 may be connected to a power source Vdd via source resistors Rs1, Rs2, and Rs3, Gates of the PMOS transistors PTr1, PTr2, and PTr3 may be connected to the power source Vdd. Bodies of the PMOS transistors PTr1, PTr2, and PTr3 may be connected to the power source Vdd. An internal circuit 12 connected to the input/output pad 11 may include a plurality of active/passive devices.

Referring to FIG. 23B, gates of the PMOS transistors PTr1, PTr2, and PTr3 may be connected to a second internal circuit 12B.

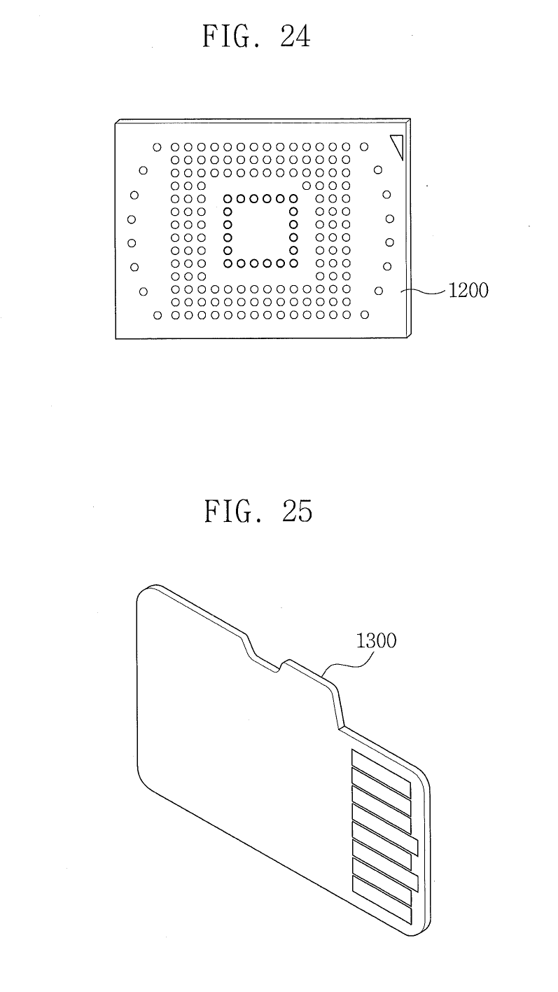

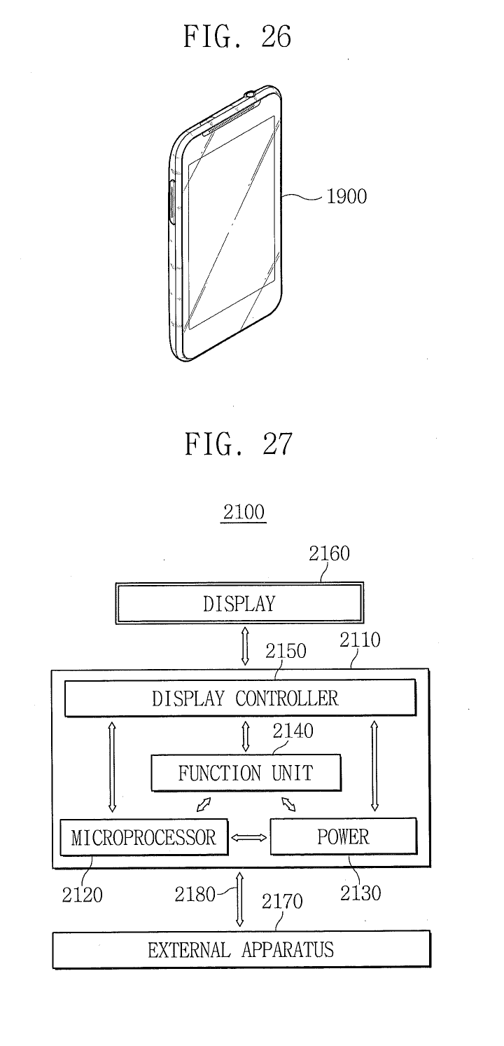

FIGS. 24 to 26 are perspective views showing electronic apparatuses in accordance with embodiments of the inventive concept, and FIG. 27 is a system block diagram of electronic apparatuses in accordance with embodiments of the inventive concept.

Referring to FIGS. 24 to 26, the semiconductor device described with reference to FIGS. 1 to 23B may be usefully applied to electronic systems, such as an embedded multi-media chip (eMMC) 1200, a micro SD 1300, a smart phone 1900, a netbook, a laptop computer, or a tablet PC. For example, the semiconductor device as described with reference to FIGS. 1 to 23B may be installed in a mainboard of the smart phone 1900. The semiconductor device as described with reference to FIGS. 1 to 23B may be provided to an expansion apparatus, such as the micro SD 1300, to be used combined with the smart phone 1900.

Referring to FIG. 27, the semiconductor device as described with reference to FIGS. 1 to 23B may be applied to an electronic system 2100. The electronic system 2100 may include a body 2110, a microprocessor unit 2120, a power unit 2130, a function unit 2140, and a display controller unit 2150. The body 2110 may be a motherboard formed of a printed circuit board (PCB). The microprocessor unit 2120, the power unit 2130, the function unit 2140, and the display controller unit 2150 may be installed on the body 2110. A display unit 2160 may be arranged inside or outside of the body 2110. For example, the display unit 2160 may be arranged on a surface of the body 2110 and display an image processed by the display controller unit 2150.

The power unit 2130 may receive a constant voltage from an external battery (not shown), etc., divide the voltage into various levels, and supply those voltages to the microprocessor unit 2120, the function unit 2140, and the display controller unit 2150, etc. The microprocessor unit 2120 may receive a voltage from the power unit 2130 to control the function unit 2140 and the display unit 2160. The function unit 2140 may perform various functions of the electronic system 2100. For example, when the electronic system 2100 is a smart phone, the function unit 2140 may have several components which perform functions of the mobile phone, such as output of an image to the display unit 2160 or output of a voice to a speaker, by dialing or communication with an external apparatus 2170. If a camera is installed, the function unit 2140 may function as a camera image processor.

In the embodiment to which the inventive concept is applied, when the electronic system 2100 is connected to a memory card, etc. in order to expand capacity, the function unit 2140 may be a memory card controller. The function unit 2140 may exchange signals with the external apparatus 2170 through a wired or wireless communication unit 2180. In addition, when the electronic system 2100 needs a universal serial bus (USB), etc. in order to expand functionality, the function unit 2140 may function as an interface controller. Further, the function unit 2140 may include a mass storage apparatus.

The semiconductor device as described with reference to FIGS. 1 to 23B may be applied to the function unit 2140 or the microprocessor unit 2120. For example, the microprocessor unit 2120 may include the dummy gate electrodes (reference numeral DG1, DG2, and DG3 in FIG. 1).

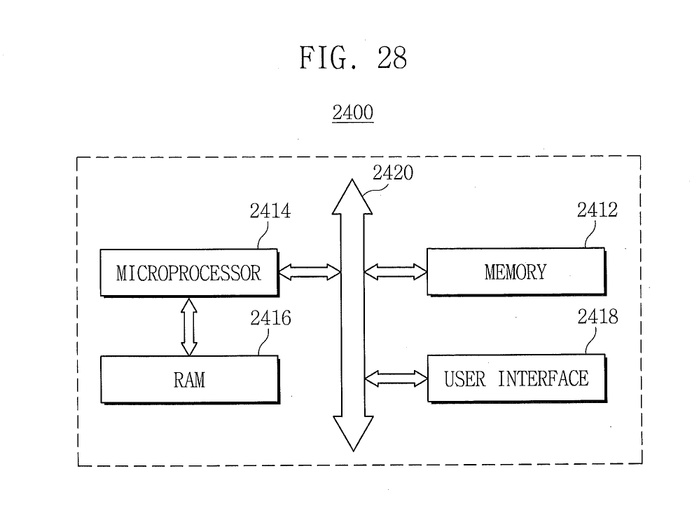

FIG. 28 is a block diagram schematically illustrating another electronic system 2400 including at least one of semiconductor devices in accordance with embodiments of the inventive concept.

Referring to FIG. 28, the electronic system 2400 may include at least one of semiconductor devices in accordance with various embodiments of the inventive concept. The electronic system 2400 may be used to fabricate a mobile apparatus or a computer. For example, the electronic system 2400 may include a memory 2412, a microprocessor 2414 performing data communication using a bus 2420, a random access memory (RAM) 2416, and a user interface 2418. The microprocessor 2414 may program and control the electronic system 2400. The RAM 2416 may be used as an operation memory of the microprocessor 2414. For example, the microprocessor 2414 or the RAM 2416 may include at least one of semiconductor devices in accordance with embodiments of the inventive concept. The microprocessor 2414, the RAM 2416, and/or other components can be assembled in a single package. The user interface 2418 may be used to input data to, or output data from the electronic system 2400. The memory 2412 may store codes for operating the microprocessor 2414, data processed by the microprocessor 2414, or external input data. The memory 2412 may include a controller and a memory device.

In accordance with various embodiments of the inventive concept, a dummy gate electrode may be provided between gate electrodes. Drain regions may be formed between the dummy gate electrodes and the gate electrodes. A drain plug and a metal silicide layer may be formed adjacent to the dummy gate electrode. The dummy gate electrode may function to control an open ratio. An ESD protection device having excellent electrical characteristics may be implemented.

The foregoing is illustrative of embodiments and is not to be construed as limiting thereof. Although a few embodiments have been described, those skilled in the art will readily appreciate that many modifications are possible without materially departing from the novel teachings and advantages. Accordingly, all such modifications are intended to be included within the scope of this inventive concept as defined in the claims. In the claims, means-plus-function clauses are intended to cover the structures described herein as performing the recited function, and not only structural equivalents but also equivalent structures.

What is claimed is:

1. An electrostatic discharge (ESD) protection device, comprising:
a fin-shaped active region defined on a substrate;
first and second gate electrodes crossing the fin-shaped active region and spaced apart from each other;
a dummy gate electrode formed between the first and second gate electrodes, crossing the fin-shaped active region, and covering a side surface of the fin-shaped active region;
a first drain region formed in the active region disposed between the first gate electrode and the dummy gate electrode;
a second drain region formed in the active region disposed between the dummy gate electrode and the second gate electrode;
a source region formed in the fin-shaped active region and spaced apart from the second drain region; and
a first drain plug connected to the second drain region,
wherein the second gate electrode is arranged between the second drain region and the source region, and each of the first and second gate electrodes covers the side surface of the fin-shaped active region, and
a distance between the first drain plug and the second gate electrode is greater than that between the first drain plug and the dummy gate electrode.

2. The ESD protection device of claim 1, further comprising:
a metal silicide layer disposed between the first drain plug and the second drain region,
wherein a distance between the metal silicide layer and the second gate electrode is greater than that between the metal silicide layer and the dummy gate electrode.

3. The ESD protection device of claim 2, further comprising:
a spacer formed on a side surface of the dummy gate electrode,
wherein the metal silicide layer is in contact with the spacer.

4. The ESD protection device of claim 3, wherein the first drain plug is in contact with the spacer.

5. The ESD protection device of claim 1, further comprising:
a second drain plug connected to the first drain region,
wherein the distance between the second drain plug and the first gate electrode is greater than that between the second drain plug and the dummy gate electrode.

6. The ESD protection device of claim 5, wherein the first and second drain plugs cover the dummy gate electrode, and are connected to each other.

7. The ESD protection device of claim 6, wherein the first and second drain plugs are in contact with the dummy gate electrode.

8. The ESD protection device of claim 1, further comprising:
a lightly doped drain (LDD) in contact with the drain region and aligned with a side surface of the second gate electrode,
wherein a first side surface of the second drain region adjacent to the second gate electrode is in contact with the LDD, and
a second side surface of the second drain region adjacent to the dummy gate electrode is in direct contact with the fin-shaped active region.

9. The ESD protection device of claim 1, further comprising:
a well formed in the fin-shaped active region under the dummy gate electrode,
wherein the fin-shaped active region includes first conductivity-type impurities,
the well, the first drain region, and the second drain region contain second conductivity-type impurities different from the first conductivity-type impurities, and
the well is arranged between the first drain region and the second drain region, and a lower end of the well is formed at a lower level than the first drain region and the second drain region.

10. The ESD protection device of claim 1, further comprising:
a third gate electrode crossing the fin-shaped active region, and spaced apart from the second gate electrode; and
a source plug formed between the second gate electrode and the third gate electrode, and connected to the source region.

11. The ESD protection device of claim 10, wherein the distance between the second gate electrode and the third gate electrode is smaller than that between the second gate electrode and the dummy gate electrode.

12. The ESD protection device of claim 1, wherein the first drain plug is connected to an input/output pad, and the first gate electrode, the second gate electrode, and the source region are connected to a ground Vss or a power source Vdd.

13. An electrostatic discharge (ESD) protection device, comprising:
an active region defined on a substrate;
first to third gate electrodes crossing the active region and spaced apart from each other;
a first dummy gate electrode formed between the first and second gate electrodes and crossing the active region;
a second dummy gate electrode formed between the second and third gate electrodes and crossing the active region;
a first drain region formed in the active region disposed between the first gate electrode and the first dummy gate electrode;
a second drain region formed in the active region disposed between the first dummy gate electrode and the second gate electrode;
a first source region formed in the active region between the second gate electrode and the second dummy gate electrode;
a second source region formed in the active region between the second dummy gate electrode and the third gate electrode;
a first drain plug adjacent to the first dummy gate electrode and connected to the second drain region; and
a first source plug adjacent to the second dummy gate electrode and connected to the first source region.

14. The ESD protection device of claim 13, further comprising:
a second drain plug connected to the first drain region; and
a second source plug connected to the second source region,
wherein the distance between the second drain plug and the first gate electrode is greater than that between the second drain plug and the first dummy gate electrode, and
the distance between the second source plug and the third gate electrode is greater than that between the second source plug and the second dummy gate electrode.

15. The ESD protection device of claim 14, wherein the first and second drain plugs cover the first dummy gate electrode, and are connected to each other and in contact with the first dummy gate electrode, and
the first and second source plugs cover the second dummy gate electrode, and are connected to each other and in contact with the second dummy gate electrode.

16. An electrostatic discharge (ESD) protection device, comprising:
a fin-shaped active region defined on a substrate;
a gate electrode crossing the fin-shaped active region;
a dummy gate electrode spaced apart from the gate electrode, crossing the fin-shaped active region;
a first drain region in the fin-shaped active region between the gate electrode and the dummy gate electrode;
a source region in the fin-shaped active region, wherein the gate electrode is between the source region and the first drain region; and
a first drain plug connected to the first drain region, wherein a distance between the first drain plug and the gate electrode is greater than a distance between the first drain plug and the dummy gate electrode.

17. The ESD protection device of claim 16, further comprising:
a second drain region formed in the fin-shaped active region, wherein the dummy gate electrode is between the first drain region and the second drain region;
a second drain plug connected to the second drain region, wherein the distance between the second drain plug and the dummy gate electrode is substantially equal to the distance between the first drain plug and the dummy gate electrode.

18. The ESD protection device of claim 17, further comprising:
a source plug connected to the source region, wherein a distance between the source plug and the gate electrode is greater than the distance between the first drain plug and the dummy gate electrode.

19. The ESD protection device of claim 16, further comprising:
a first gate dielectric layer surrounding bottom and side surfaces of the gate electrode and dummy gate electrode;
second gate dielectric layer between the fin-shaped active region and the first gate dielectric layer;
a first interlayer insulating layer; and
a second interlayer insulating layer on the first interlayer insulating layer, wherein upper ends of the first interlayer insulating layer, the gate electrode and the dummy gate electrode are substantially on the same plane.

20. The ESD protection device of claim 16, wherein the first drain region is connected to a first active circuit, the gate electrode is connected to a second active circuit and the source region is connected to ground.
